(19) United States
(12) Patent Application Publication
(10) Pub. No.: US 2008/0109689 A1
(43) Pub. Date: May 8, 2008

(54) Test system improving signal integrity by restraining wave reflection

(75) Inventor: Ki-Jae Song, Paju-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/974,543

(22) Filed: Oct. 15, 2007

(30) Foreign Application Priority Data
Nov. 7, 2006 (KR) 10-2006-0109460

(51) Int. Cl. G11C 29/00

(52) U.S. Cl. 714/718

(57) ABSTRACT

A test system that tests a plurality of memories comprises a tester, a test board coupled to the tester, and a transmission line. The test board includes the plurality of memories. A transmission line connects the memories to each other in parallel. The test board includes a compensating unit that compensates for signal distortion on the transmission line.

### CROSS-REFERENCE TO RELATED APPLICATIONS

This U.S. non-provisional patent application claims priority under 35 U.S.C. § 119 of Korean Patent Application No. 10-2006-0109460 filed on November 7, 2006, the entire contents of which are hereby incorporated by reference.

### BACKGROUND

The present invention disclosed herein relates to test systems and more particularly, to a fast (or high-frequency) memory test system using a frequency divider.

Many electronics applications are now demanding an increase in rates in memories. To correspond with those demands, memory manufacturers are producing memories that operate at high frequencies (or high data rate). In evaluating such fast memories, it is essential to perform a package test process on the memories. The memory manufacturers test a number of memories at a time to reduce a product cost of a backend process. In particular, the package test process may include a test system that transfers a test pattern to a plurality of memories through a frequency divider on a test board.

There is no trouble when a test system transfers data to a plurality of slow (or low-frequency) memories through a frequency divider. However, when a test system transfers data to pluralities of fast memories through a frequency divider, the capacitance resident in the fast memories becomes larger due to an increase in the time constant, which can deteriorate characteristics of input signals transferred to the fast memories in the test system.

### SUMMARY OF THE INVENTION

The present invention is directed to provide a test system improving signal identity on an operating frequency band of fast memories by means of frequency-divided transmission lines.

In accordance with an aspect of the present invention, a test system that tests a plurality of memories comprises a tester, a test board coupled to the tester, the test board including the plurality of memories, and a transmission line that connects the memories to each other in parallel, wherein the test board includes a compensating unit that compensates for signal distortion on the transmission line.

In an embodiment, the compensating unit comprises at least one inductor. In an embodiment, the at least one inductor is connected to the transmission line.

In an embodiment, a reflection wave is minimized at an operating frequency of the plurality of memories.

In an embodiment, a resonant frequency is optimized at an operating frequency of the plurality of memories.

In an embodiment, an eye-open size is maximized by increasing an LR time constant on an operating frequency of the plurality of memories.

In an embodiment, the tester applies a test pattern through the transmission line so as to test the plurality of memories.

In an embodiment, the plurality of memories receives a test pattern and outputs results of the test pattern in sequence.

In an embodiment, the transmission line is connected between the tester and the memories.

In an embodiment, the transmission line comprises inter-memory transmission lines that connect each memory to the tester.

In accordance with another aspect of the present invention, a method of testing a plurality of memories comprises providing a tester, coupling a test board to the tester, the test board including the plurality of memories, connecting the memories to each other in parallel via a transmission line, and compensating for signal distortion on the transmission line.

In an embodiment, a compensating unit compensates for the signal distortion, the compensating unit comprising at least one inductor. In an embodiment, connecting the memories to each other in parallel comprises connecting the at least one inductor to a transmission line that is coupled to the tester.

In an embodiment, compensating for the signal distortion comprises minimizing a reflection wave at an operating frequency of the plurality of memories.

In an embodiment, compensating for the signal distortion comprises optimizing a resonant frequency at an operating frequency of the plurality of memories.

In an embodiment, compensating for the signal distortion includes maximizing an eye-open size by increasing an LR time constant on an operating frequency of the plurality of memories.

In an embodiment, the method further comprises applying a test pattern by the tester to test the plurality of memories.

In an embodiment, the plurality of memories receives a test pattern and outputs results of the test pattern in sequence.

A further understanding of the nature and advantages of the present invention herein may be realized by reference to the remaining portions of the specification and the attached drawings.

### BRIEF DESCRIPTION OF THE FIGURES

Non-limiting and non-exhaustive embodiments of the present invention will be described with reference to the following figures, wherein like reference numerals refer to like parts throughout the various figures unless otherwise specified. The drawings are not necessarily to scale, emphasis instead being placed upon illustrating aspects of the invention. In the figures:

FIG. 1 is a block diagram of a test system for testing high-frequency memories by way of a frequency divider in accordance with embodiments of the invention;

FIG. 2 is a block diagram of the test system of FIG. 1 illustrating modeling the memories of FIG. 1 on inductors and capacitors in accordance with embodiments of the invention;

FIG. 3 is a block diagram illustrating the inductors and capacitors of the memory models of FIG. 2 reduced by an equivalent model that includes a single inductor and capacitor in accordance with embodiments of the invention;

FIG. 4 is a graphic diagram comparing frequencies to noises in the memory model of FIG. 3;

FIG. 5 is a block diagram of a test system in accordance with embodiments of the present invention.

FIG. 6 is a block diagram illustrating the capacitors and inductors of FIG. 5 reduced by an equivalent model that includes two inductors and one capacitor in accordance with embodiments of the invention;

FIG. 7 is a graphic diagram comparing frequencies to noises in the memory model of FIG. 6;

FIG. 8 is a graph showing a signal characteristic by an eye-diagram on a memory operation rate of 800 Mbps as a general case;

FIG. 9 is a graph showing a signal characteristic by an eye-diagram on a memory operation rate of 800 Mbps if an inductor is inserted into a test board;

FIG. 10 is a graph showing the signal integrity by an eye-diagram on a memory operation rate of 1080 Mbps as a general case; and

FIG. 11 is a graph showing the signal integrity by an eye-diagram on a memory operation rate of 1080 Mbps if the inductor is inserted into a test board.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout the accompanying figures.

In the figures, the dimensions of layers and regions are exaggerated for clarity of illustration. It will also be understood that when a layer is referred to as being ‘on’ another layer or substrate, it can be directly on the other layer or substrate, or intervening layers may also be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

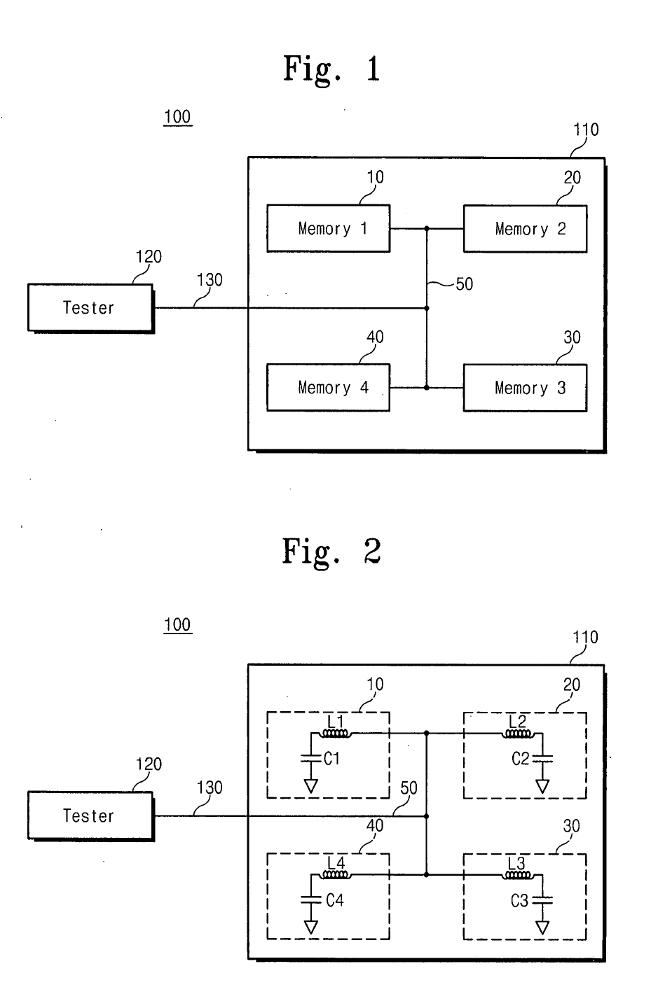

FIG. 1 is a block diagram of a test system for testing high-frequency memories by means of a frequency divider. Referring to FIG. 1, the test system 100 is comprised of a test board 110, a tester 120, and a transmission line 130.

The tester 120 transfers a test pattern to the transmission line 130 so as to test memories 10, 20, 30, and 40 (10˜40) on the test board 110. The test pattern is transferred through transmission line 130 to the memories 10˜40 via inter-memory transmission lines 50. Each memory 10˜40 transfers a result of the test pattern to the tester 120.

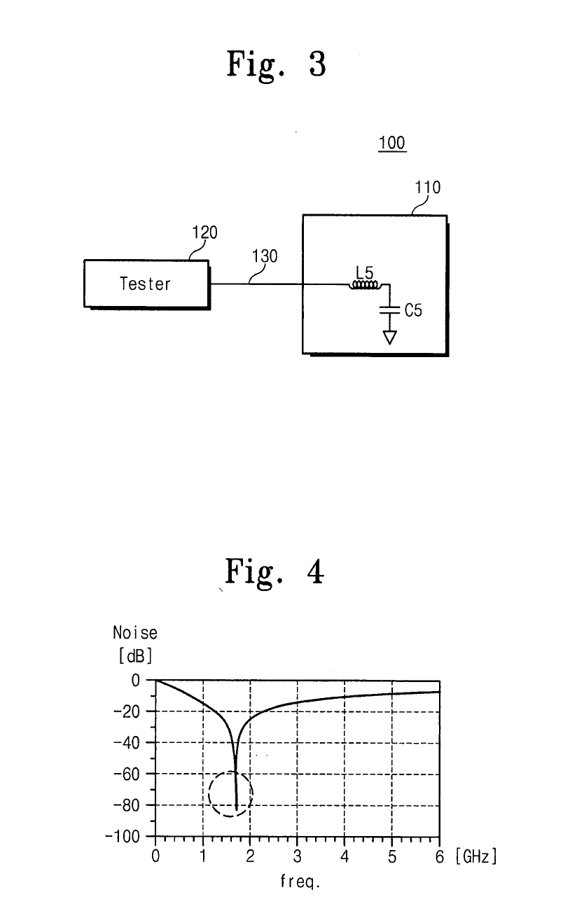

FIG. 2 is a block diagram of the test system of FIG. 1 illustrating modeling the memories 10˜40 of FIG. 1 on inductors and capacitors in accordance with embodiments of the invention. FIG. 3 is a block diagram illustrating the inductors and capacitors of the memory models of FIG. 2 reduced by an equivalent model that includes a single inductor and capacitor in accordance with embodiments of the invention, and FIG. 4 is a graphic diagram comparing frequencies to noises in the memory model of FIG. 3.

Referring to FIG. 2, the memories 10˜40 divided by the transmission line 130 can be transformed in an equivalent model of inductors L1˜L4 and capacitors C1˜C4.

For example, the first memory 10 is modeled on a first inductor L1 and a first capacitor C1. Namely, the first inductor L1 is connected between the transmission line 130 and the first capacitor C1. The first capacitor C1 is connected between the first inductor L1 and the ground voltage. The second memory 20 is modeled on a second inductor L2 and a second capacitor C2. Namely, the second inductor L2 is connected between the transmission line 130 and the second capacitor C2. The second capacitor C2 is connected between the second inductor L2 and the ground voltage. The third memory 30 is modeled on a third inductor L3 and a third capacitor C3. Namely, the third inductor L3 is connected between the transmission line 130 and the third capacitor C3. The third capacitor C3 is connected between the third inductor L3 and the ground voltage. The fourth memory 40 is modeled on a fourth inductor L4 and a fourth capacitor C4. Namely, the fourth inductor L4 is connected between the transmission line 130 and the fourth capacitor C4. The fourth capacitor C4 is connected between the fourth inductor L4 and the ground voltage.

As illustrated in FIG. 2, since each memory 10˜40 is composed of an inductor-capacitor pair among the inductors L1˜L4 and the capacitors C1˜C4, the total inductance becomes smaller, while the total capacitance becomes larger. That is, as shown in FIG. 3, a model of each memory can be formed of the single inductor and capacitor.

L1=L2=L3=L4=L [Equation 1]

C1=C2=C3=C4=C [Equation 2]

L5=L/4 [Equation 3]

C5=4*C [Equation 4]

Assuming that the inductors are the same with each other in inductance, and the capacitors are the same with each other in capacitance, as shown by Equations 1 and 2, the total inductance L5 and the total capacitance C5 may be represented each in Equations 3 and 4.

For example, assuming that in the memories 10˜40, the inductors L1˜L4 have the same inductance (3 nH) and the capacitors C1˜C4 have the same conductance (3 pF), the total inductance L5 is 0.75 nH and the total capacitance C5 is 12 pF.

$$\begin{matrix}{ω}_{0} = \frac{1}{\sqrt{L \cdot C}} & [ Equation 5 ] \\ {f}_{0} = \frac{{ω}_{0}}{2 \cdot π} & [ Equation 6 ]\end{matrix}$$

Putting L5 and C5 into Equations 5 and 6, it can be obtained as follows.

$${ω}_{0} = \frac{1}{\sqrt{0.75 \cdot {10}^{- 9} \times {1210}^{- 12}}} = 10.4 \times {10}^{9}$$

$${f}_{0} = \frac{10.4 \times {10}^{9}}{2 \cdot π} = 1.6 \times {10}^{9} = 1.65 GHz \qquad [ Equation 6 ]$$

An operating frequency of the test system with the memory shown in FIG. 3 is 400 MHz, whereas the resonant frequency is 1.65 GHz in the graph shown in FIG. 4. In other words, as a reflection wave becomes the smallest at the band of 1.65 GHz, it is relatively larger at other frequency bands. The reflection wave means a ratio of a received signal to a transmitted signal. As a rate of the reflection wave is smaller, a signal is transferred having a smaller loss.

Thus, if there is a large reflection wave in the operating frequency of the memory, for example, frequency bands other than the band at 1.65 GHz, it deteriorates the signal identity on the operating frequency band.

According to the present invention, the induction of the reflection wave is restrained by changing the resonant frequency to be closer to the operating frequency of the memory. Thus, it improves the signal identity of the test system.

Also, the present invention compensates for a lowered inductance value by parallel connection with an inductor inserted into the input of a frequency divider on a test board. Therefore, a reflection wave is minimized because a resonant frequency is generated at an operating frequency band of the memory to be tested.

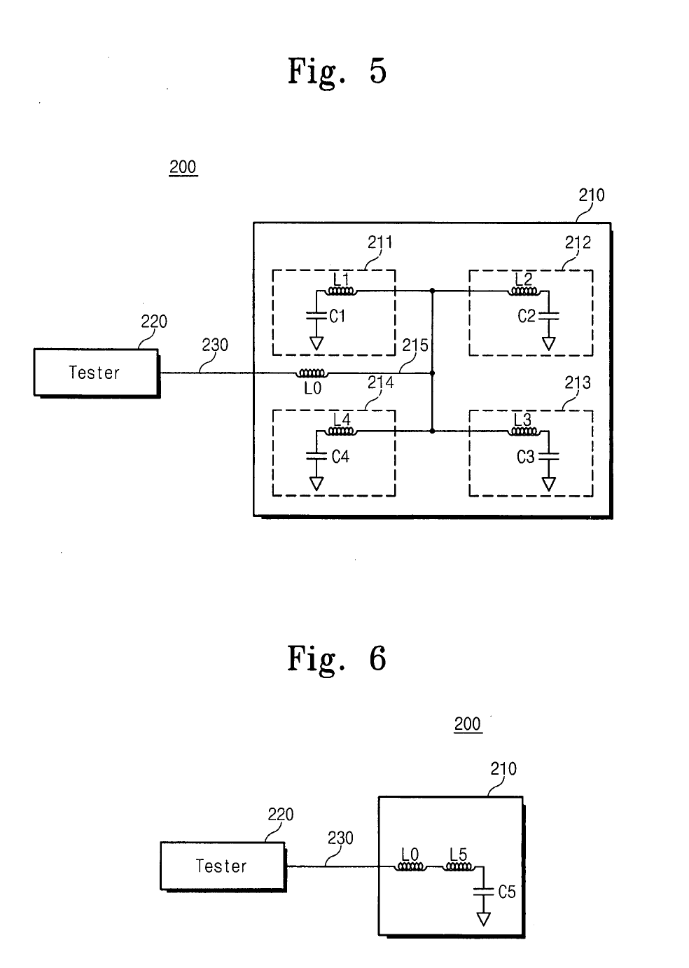

FIG. 5 is a block diagram illustrating a test system in accordance with embodiments of the present invention. The test system 200 shown in FIG. 5 is similar to the test system 100 shown in FIG. 2, so descriptions related to elements common to both FIG. 2 and FIG. 5 will not be repeated. Referring to FIG. 5, the test system 200 is comprised of a test board 210 including memories, a tester 220, and a transmission line 230. The test board 210 includes an inductor L0 for shifting the resonant frequency to the operating frequency.

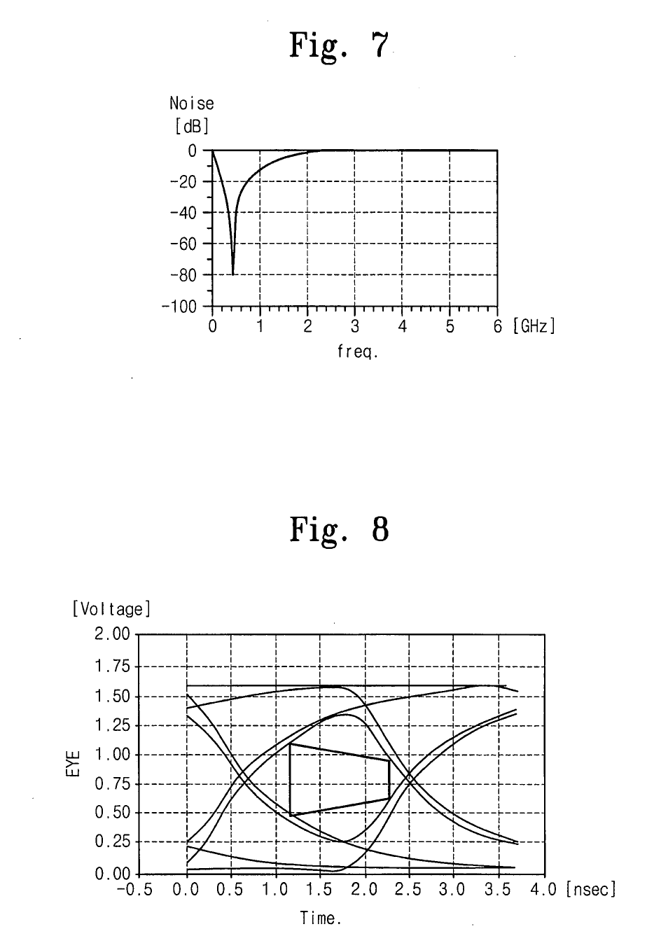

FIG. 6 is a block diagram illustrating the capacitors and inductors of FIG. 5 reduced by an equivalent model that includes two inductors and one capacitor in accordance with embodiments of the invention and FIG. 7 is a graphic diagram comparing frequencies to noises in the memory model of FIG. 6.

Referring to FIG. 6, the memories 211˜214 and the inductor L0 can be equivalently modeled on the first inductor L0, the second inductor L5, and a single capacitor C5.

For instance, assuming that in the memories 211˜214, the inductors L1˜L4 have the same inductance (3 nH) and the capacitors C1˜C4 have the same conductance (3 pF), the total inductance L5 becomes 0.75 nH by applying Equation 3 above and the total capacitance becomes 12 pF by applying Equation 4 above.

$$L = \frac{1}{C} \cdot {( \frac{1}{2 π {f}_{0}} )}^{2} \qquad [ Equation 7 ]$$

Assuming that the operating frequency f₀ of each memory is 400 MHz, Equation 7 is able to obtain the inductance of the inductor L0 inserted into the input. Equation 7 hereinafter results from arranging Equations 5 and 6 accordingly.

The inductance of the inductor L0 inserted at the input of the test board is 13.2 nH.

$$L = \frac{1}{12 \times {10}^{- 9} } \cdot {( \frac{1}{2 π \cdot 400 \times {10}^{6}} )}^{2} = 13.2 \times {10}^{- 9}$$

According to the present invention, the inductor added to the test board contributes to optimize the resonant frequency on the operating frequency of the memory. Thus, the inductance of the divided memory is controlled to make the memory resonate at its operating frequency, minimizing wave reflection of an input signal and hence improving the eye-window characteristics.

In addition, in another embodiment, the resonant frequency is shifted to the operating frequency of the memory by combining another device unit, but the inductor, to the test board. For instance, it is permissible to use a combination of inductor and capacitor, or a capacitor in order to shift a frequency of an input signal on the test board.

The improvement of signal integrity may be found by comparing eye-window levels from an eye-diagram.

The eye-diagram is used to plot eye-shaped waves when binary data, for example binary data of ‘001’, ‘010’, ‘011’, ‘100’, ‘101’, and ‘110, are applied to an input signal. From the eye-diagram, a large window size of an “eye-open” is indicative of a test system having improved signal integrity relative to a small window size of an “eye-open.” In an embodiment, an eye-open window size is maximized by increasing an LR time constant on an operating frequency of the memories.

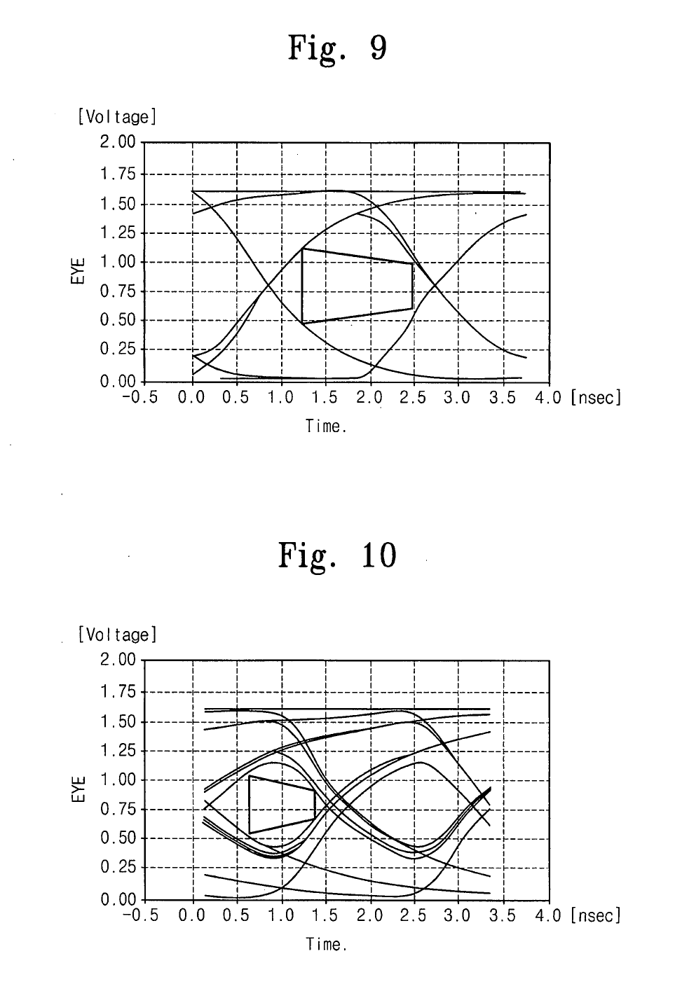

FIG. 8 is a graph showing the signal integrity by an eye-diagram on a memory operation rate of 800 Mbps as a general case, and FIG. 9 is a graph showing the signal integrity by an eye-diagram on a memory operation rate of 800 Mbps if the inductor is inserted into the test board.

Referring to FIGS. 8 and 9, FIG. 8 is larger than FIG. 9 in eye-open window size. In other words, the case with the inductor is better than the general case in eye-open size by about 10%.

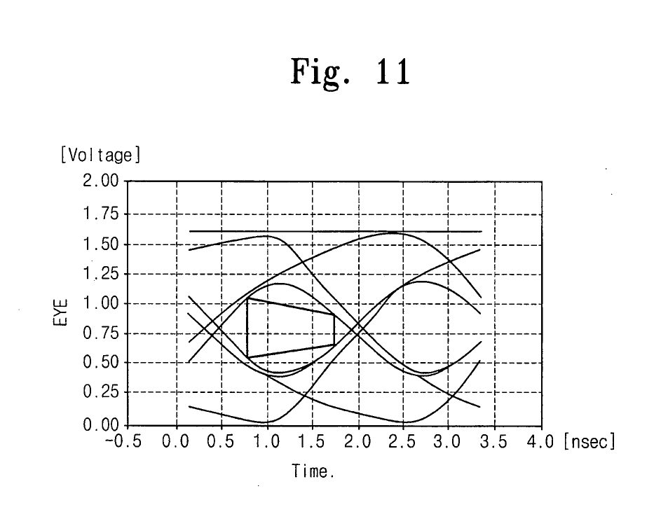

FIG. 10 is a graph showing the signal integrity by an eye-diagram on a memory operation rate of 1080 Mbps as a general case, and FIG. 11 is a graph showing the signal integrity by an eye-diagram on a memory operation rate of 1080 Mbps if an inductor is inserted into the test board. Referring to FIGS. 10 and 11, FIG. 8 is larger than FIG. 9 in eye-open window size. In other words, it can be seen that there is an improvement about 12% in the case of inserting the optimized inductance with four-divisional memories under the operation rate of 1080 MHz.

In summary, the present invention has an advantage in that an inductor is inserted into a test board contributes to optimization of the resonant frequency on the operating frequency of the memory. Therefore, the inductance of the divided memory is controlled to make the memory resonate at its operating frequency, thereby minimizing wave reflection of an input signal and hence improving the eye-window characteristics.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A test system that tests a plurality of memories comprising:
a tester;
a test board coupled to the tester, the test board including the plurality of memories; and
a transmission line that connects the memories to each other in parallel, wherein the test board includes a compensating unit that compensates for signal distortion on the transmission line.

2. The test system as set forth in claim 1, wherein the compensating unit comprises at least one inductor.

3. The test system as set forth in claim 2, wherein the at least one inductor is connected to the transmission line.

4. The test system as set forth in claim 1, wherein a reflection wave is minimized at an operating frequency of the plurality of memories.

5. The test system as set forth in claim 1, wherein a resonant frequency is optimized at an operating frequency of the plurality of memories.

6. The test system as set forth in claim 1, wherein an eye-open size is maximized by increasing an LR time constant on an operating frequency of the plurality of memories.

7. The test system as set forth in claim 1, wherein the tester applies a test pattern through the transmission line so as to test the plurality of memories.

8. The test system as set forth in claim 1, wherein the plurality of memories receives a test pattern and outputs results of the test pattern in sequence.

9. The test system as set forth in claim 1, wherein the transmission line is connected between the tester and the memories.

10. The test system as set forth in claim 1, wherein the transmission line comprises inter-memory transmission lines that connect each memory to the tester.

11. A method of testing a plurality of memories comprising:
providing a tester;
coupling a test board to the tester, the test board including the plurality of memories;
connecting the memories to each other in parallel via a transmission line; and
compensating for signal distortion on the transmission line.

12. The method as set forth in claim 11, wherein a compensating unit compensates for the signal distortion, the compensating unit comprising at least one inductor.

13. The method as set forth in claim 12, wherein connecting the memories to each other in parallel comprises connecting the at least one inductor to a transmission line that is coupled to the tester.

14. The method as set forth in claim 11, wherein compensating for the signal distortion comprises minimizing a reflection wave at an operating frequency of the plurality of memories.

15. The method as set forth in claim 11, wherein compensating for the signal distortion comprises optimizing a resonant frequency at an operating frequency of the plurality of memories.

16. The method as set forth in claim 11, wherein compensating for the signal distortion includes maximizing an eye-open size by increasing an LR time constant on an operating frequency of the plurality of memories.

17. The method as set forth in claim 11 further comprising applying a test pattern by the tester to test the plurality of memories.

18. The method as set forth in claim 11, wherein the plurality of memories receives a test pattern and outputs results of the test pattern in sequence.
